(19) United States
(12) Patent Application Publication
(10) Pub. No.: US 2009/0237116 A1
(43) Pub. Date: Sep. 24, 2009

(54) RECEIVING DEVICE

(75) Inventors: Hiroshi FUKAYA, Kawasaki (JP); Takashi Kaiga, Kawasaki (JP); Masaki Kubo, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 12/403,644

(22) Filed: Mar. 13, 2009

(30) Foreign Application Priority Data
Mar. 19, 2008 (JP) 2008-071491

(51) Int. Cl. H03D 13/00

(52) U.S. Cl. 327/3

(57) ABSTRACT

A receiving device for receiving a parallel-data including a clock and a plurality of data signals, the receiving device includes a plurality of data capturing circuits for receiving the data signal and the clock, respectively, the data capturing circuit capturing the data signal of the parallel-data on the bases of the clock; a plurality of phase comparing circuits for receiving the data signal and the clock, respectively, the phase comparing circuit capturing the clock of the parallel-data on the bases of the each data in order to compare a phase between the clock and the data signal; and an aggregating circuit for monitoring a relationship between the clock and the data signals on the bases of comparison results from the plurality of phase comparing circuits.

### CROSS-REFERENCE TO RELATED APPLICATION

This application is based upon and claims the benefit of priority of the prior Japanese Patent Application No. 2008-71491, filed on Mar. 19, 2008, the entire contents of which are incorporated herein by reference.

### FIELD

The present invention relates to a parallel-data receiving device and a receiving method for receiving a clock signal and multiple data signals, and relates to a parallel-data receiving device and a receiving method for monitoring the phase relationship between a clock and data.

### BACKGROUND

Conventionally, for transmission of parallel signals, for example, error detection as disclosed in Japanese Laid-open Patent Publication No. 2003-174433 and monitoring of a phase relationship between a clock and data through the use of a configuration illustrated in FIGS. 14 and 15 have been performed.

In the conventional parallel-data transfer configuration illustrated in FIG. 14, in order to calculate and transmit vertical parities between parallel data at a physical layer in addition to transmission of parallel data and a clock at a high-level layer application software, the number of lines for monitoring signals is increased by 1 and a receiving unit performs monitoring.

Specifically, as illustrated in FIG. 15, when alarm information is confirmed in either error checking (step S201) at the physical layer or error checking (step S202) at the high-level layer application software, abnormality detection is executed (step S204). When an abnormality is detected, an alarm is issued (step S204), and when no abnormality exists, an alarm is terminated (step S203).

The conventional technology has a problem that is power consumption for the insertion circuit for parity calculation results and a checking circuit for the parity calculation results, and the another transmission line.

### SUMMARY

According to an aspect of the invention, a receiving device for receiving a parallel-data including a clock and a plurality of data signals, the receiving device includes a plurality of data capturing circuits for receiving the data signal and the clock, respectively, the data capturing circuit capturing the data signal of the parallel-data on the bases of the clock; a plurality of phase comparing circuits for receiving the data signal and the clock, respectively, the phase comparing circuit capturing the clock of the parallel-data on the bases of the each data in order to compare a phase between the clock and the data signal; and an aggregating circuit for monitoring a relationship between the clock and the data signals on the bases of comparison results from the plurality of phase comparing circuits.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is a schematic configuration diagram illustrating a schematic configuration of a parallel-data receiving device according to the present invention.

FIG. 2 is an illustration diagram illustrating an example of a specific circuit configuration of a receiving device 1.

FIG. 3 is a time chart illustrating a processing operation of the receiving device 1.

FIG. 4 is a schematic configuration diagram illustrating a schematic configuration of a receiving device in which the duty ratio of a reception clock is varied.

FIG. 5 is an illustration diagram illustrating an example of a specific circuit configuration of a receiving device 2.

FIG. 6 is a time chart illustrating a processing operation of the receiving device 2.

FIG. 7 is a schematic configuration diagram illustrating a schematic configuration of a receiving device for resolving an abnormality by performing phase control of a clock signal.

FIG. 8 is an illustration diagram illustrating an example of a specific circuit configuration of a receiving device 3.

FIG. 9 is a time chart illustrating a processing operation of the receiving device 3.

FIG. 10 is a schematic configuration diagram illustrating a schematic configuration of a receiving device for resolving an abnormality by performing phase control of data signals.

FIG. 11 is an illustration diagram illustrating an example of a specific circuit configuration of a receiving device 4.

FIG. 12 is a time chart illustrating a processing operation of the receiving device 4.

FIG. 13 is a flowchart illustrating a processing operation for phase abnormality detection.

FIG. 14 is an illustration diagram illustrating abnormality detection performed by a conventional parallel-data receiving device.

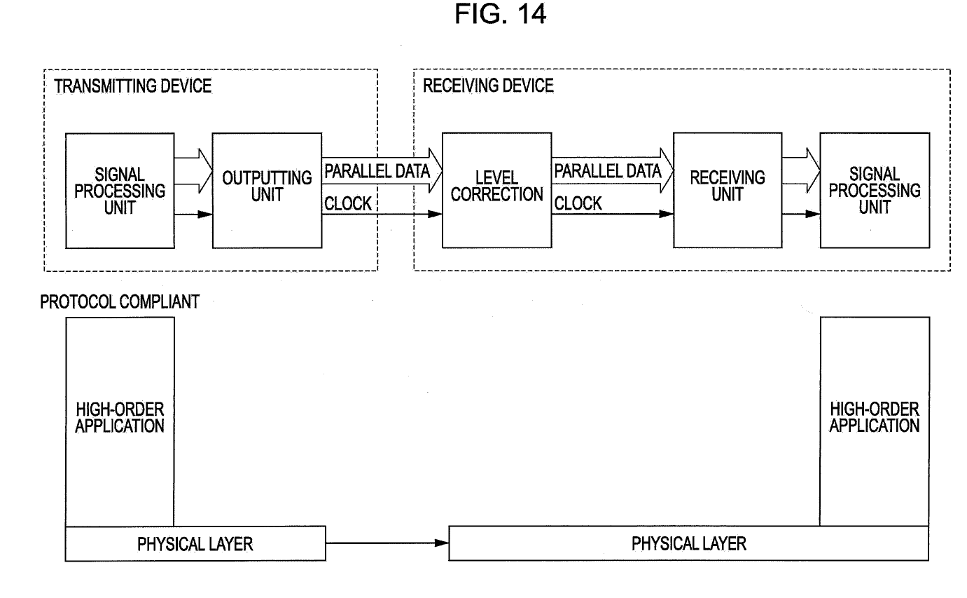

FIG. 15 is a flowchart illustrating abnormality detection processing performed by the conventional parallel-data receiving device.

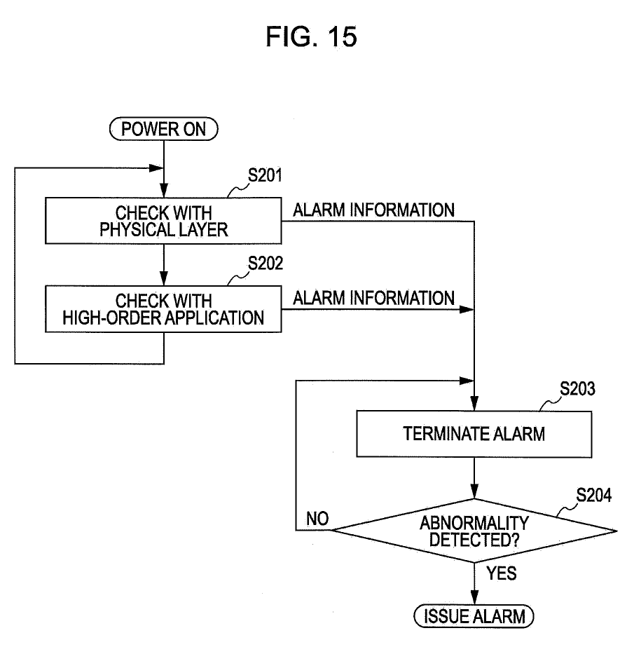

### DESCRIPTION OF EMBODIMENT

A parallel-data receiving device and a parallel-data receiving method according to the present embodiments will be described below in detail based on the drawings.

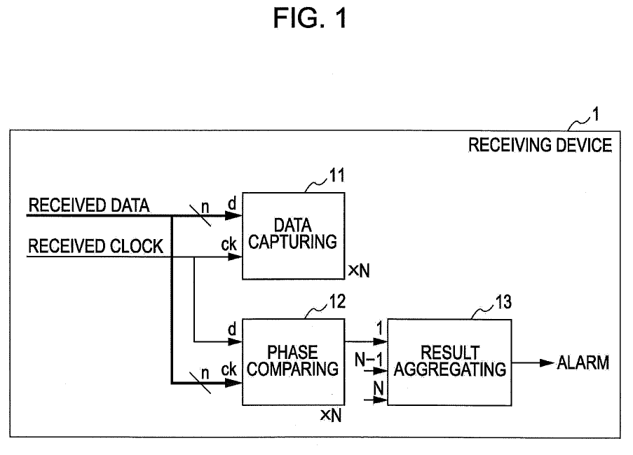

FIG. 1 is a schematic configuration diagram illustrating a schematic configuration of a parallel-data receiving device. A receiving device 1 illustrated in the figure has, therein, N data capturing circuits 11, N phase comparing circuits 12, and a result aggregating circuit 13.

The receiving device 1 is connected to N data signal lines and one clock signal line. The data capturing circuits 11 and the N phase comparing circuits 12 correspond to N data signal lines, respectively.

In response to a clock signal and one of N data signals of the N lines, the data capturing circuit 11 captures the data signal on the basis of clock information indicating by the clock signal. Specifically, the data capturing circuit 11 has a data terminal d and a clock terminal ck, and one of the data signal lines is connected to the data terminal d and the clock signal line is connected to the clock terminal ck.

Upon receiving the clock signal and one of the data signals, the phase comparing circuit 12 uses a change in the data signal as a clock and captures the clock signal as data, to thereby compare the phase of the data signal with the phase of the clock signal. Specifically, the phase comparing unit 12 has a data terminal d and a clock terminal ck, and the clock signal line is connected to the data terminal d and one of the data signal lines is connected to the clock terminal ck.

The result aggregating circuit 13 then aggregates comparison results of the N phase comparing circuits 12 and functions as a phase monitoring unit for monitoring phase relationships between the clock signals and the data signals.

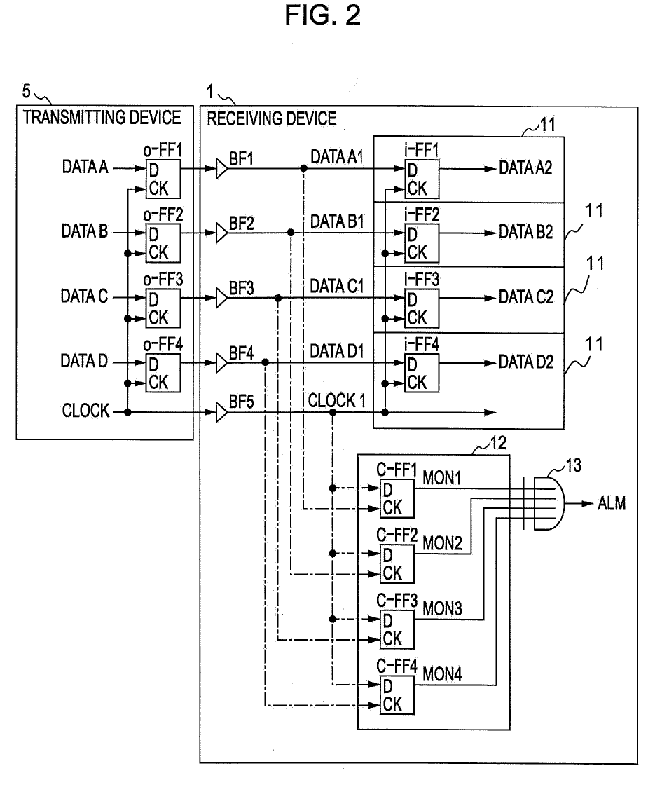

FIG. 2 is an illustration diagram illustrating an example of a specific circuit configuration of the receiving device 1. The receiving device 1 in the configuration example illustrated in the figure is connected to a transmitting device 5 through four data signal lines and one clock signal.

After being buffered by buffers BF1-BF4, four data signal lines are supplied data signal to the data capturing circuits 11 and the phase comparing circuits 12.

The data capturing units 11 are realized data signals by flip flops i-FF1˜i-FF4, respectively, and the phase comparing circuits 12 are realized by flip flops c-FF1˜c-FF4. An exclusive OR circuit (E-OR) is used as the result aggregating circuit 13.

The flip flops c-FF1˜c-FF4 use the received clock signals as data inputs d and uses the received data signals as clock inputs ck. MONs 1˜4, which are outputs of the flip flops c-FF1˜c-FF4, are connected to the result aggregating circuit 13.

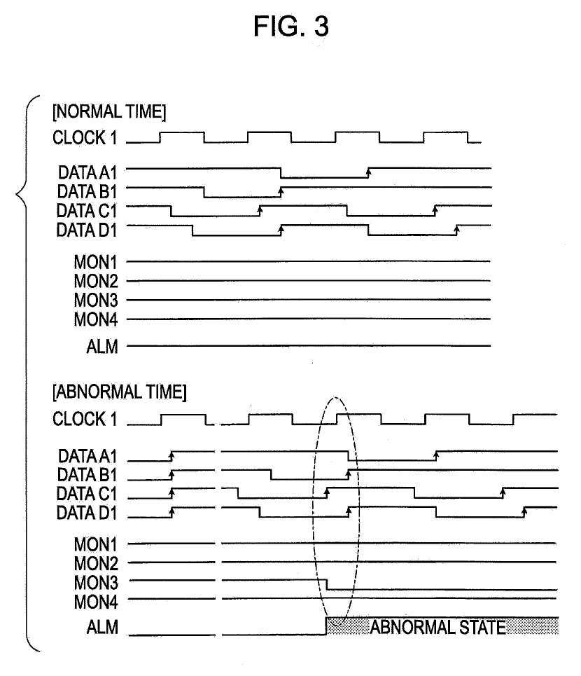

FIG. 3 is a time chart illustrating a processing operation of the receiving device 1. As illustrated in the figure, when the phases of the clock and the data are normal, the rising edges (the transition from a high state to a low state) of the data signals always occur when the clock signal is in a high state (“H” state).

As described above, each of the phase comparing circuits 12 inputs the data signal as a clock and inputs the clock signal as data. Thus, when the received clock signal is viewed using, as a clock, the timing at which the data signal rises, the received clock signal should always be in the high state in the normal state.

On the other hand, in an abnormal state in which the received clock is delayed more than or equal to delay variations of the data lines, the low state of the received clock appears at the rising edge of the received data. In the abnormal time in the timing chart illustrated in FIG. 3, the rising edge of data C1 occurs when a clock 1 is in the low state, because of the signal delay of the data C1.

Accordingly, when the rising edge of the data in any of the phase comparing circuits 12 occurs when the clock signal is in the low state, the result aggregating circuit 13 determines that a phase abnormality has occurred.

That is, when the phases of the parallel data are in the “H” area of the clock, the MONs 1˜4 output “H”. In this case, it can be simply determined that the phases of individual pieces of the parallel data are within the same clock.

As described above, in a communication system designed on the premise that data from a transmitting device arrive with a specified delay, the sections of the “H” level and the “L” level of the transmission clock are used to detect the phases of the signals. In FIGS. 1 to 3, phase checking is performed on the premise that change points of data can be received when the clock is in the “H” section. Thus, when the output value of the phase comparing circuit 12 becomes “L”, it can be determined that the phase is in the phase abnormality state. Also, since the flip flops in the phase comparing circuits 12 are fixed to either “H” or “L”, the amount of power consumption is smaller than that of the parity calculating circuit of the conventional technology.

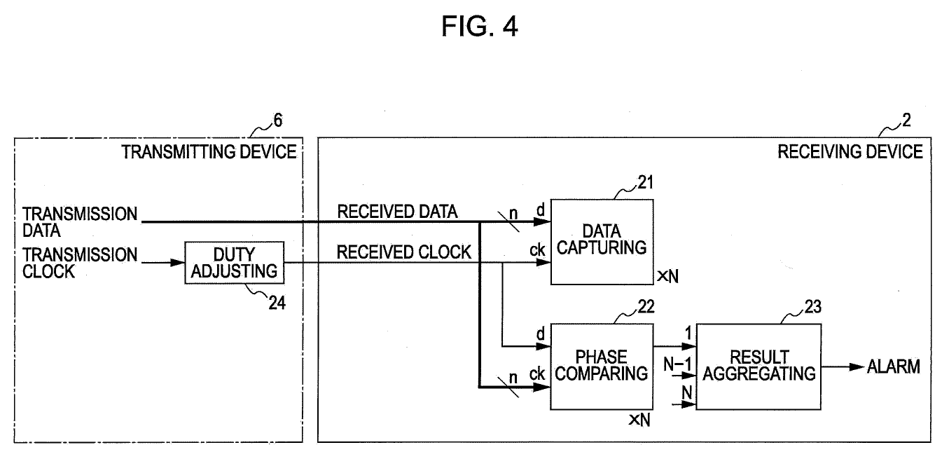

A modification of the present invention will be described next with reference to FIG. 4. In the configuration illustrated in FIG. 4, a transmitting device 6 has a duty adjusting circuit 24 for adjusting a duty ratio (duty ratio) of a clock signal, and data capturing circuits 21 and phase comparing circuits 22 in a receiving device 2 receive the clock signal whose duty ratio was adjusted by the transmitting side.

In the receiving device 2, the received data is input to terminals “d” of the data capturing circuits 21 and terminals “ck” of the phase comparing circuits 22, the received clock is input to terminals “ck” of the data capturing circuits 21 and terminals “d” of the phase comparing circuits 22, and the phase relationships between the data and the clocks are compared. As in the receiving device 1, outputs of comparison results are input to a result aggregating circuit 23 and are aggregated to provide an interface alarm.

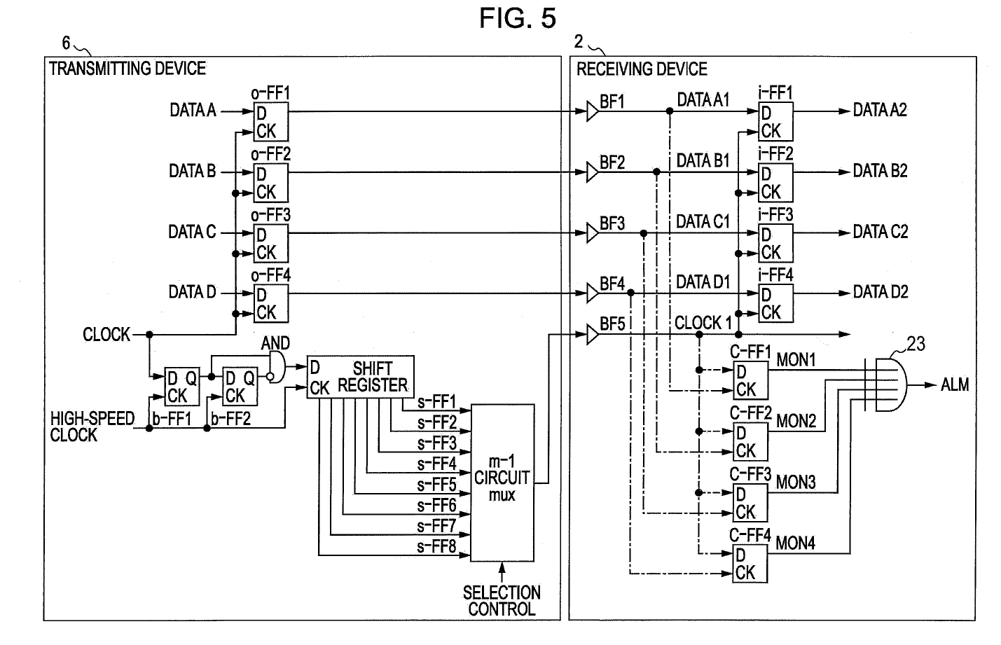

FIG. 5 illustrates an example of the circuit configuration of the parallel-data transmission configuration illustrated in FIG. 4. In the circuit configuration illustrated in FIG. 5, the transmitting device 6 has flip flop circuits b-ff1 and b-ff2 for differentiating a transmission clock, an AND circuit, shift registers s-ff1˜8 for shifting differentiation values, and an m-1 circuit mux for multiplexing the shifted differentiation results in accordance with external control. This makes it possible to achieve a circuit that transmits a clock at “L” with reference to the setup/hold times of the reception flip flops i-FF1˜4 and that transmits a clock at H” during other times.

Then, the receiving device 2 determines that phases at the reception flip flops are normal, when output values of C-FF1˜4 are “H”, and determines that the reception flip flops lack margins, when the output values of C-FF1˜4 become “L”.

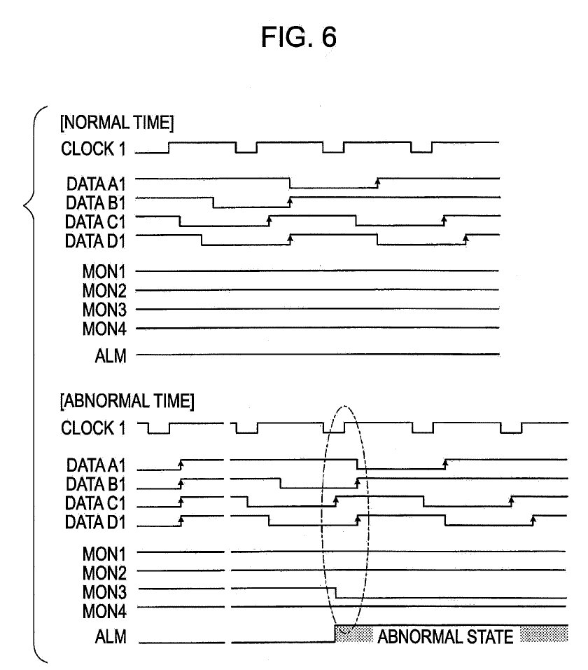

This operation will be described with reference to FIG. 6. Since the transmitting side adjusts the duty ratio of the clock signal, the width of the high state of the clock signal is larger than the width of the low state thereof, as illustrated in the figure. When a determination is made based on the clock signal, as in the receiving device 1, a range (a margin) in which it is determined that the clock is normal is increased by an amount corresponding to the extended time of the high state. Nevertheless, if the clock is still put into the low state (see data C-1 [abnormal time] in the figure), it is determined that a phase abnormality has occurred.

As described above, the clock-duty adjusting circuit 24 in the transmitting device 6 varies the duty ratio of the transmission clock. This is to say, the clock-duty adjusting circuit 24 sets the “L” section with reference to the setup/hold times of the flip flops inside the data capturing circuits 21. After that, the clock-duty adjusting circuit 24 transmits the resulting transmission clocks. In this state, when the setup/hold time of the data capturing circuit 21 is satisfied, “H” is output from the phase comparing circuit 22 and it can be determined that the phase is a phase normal state.

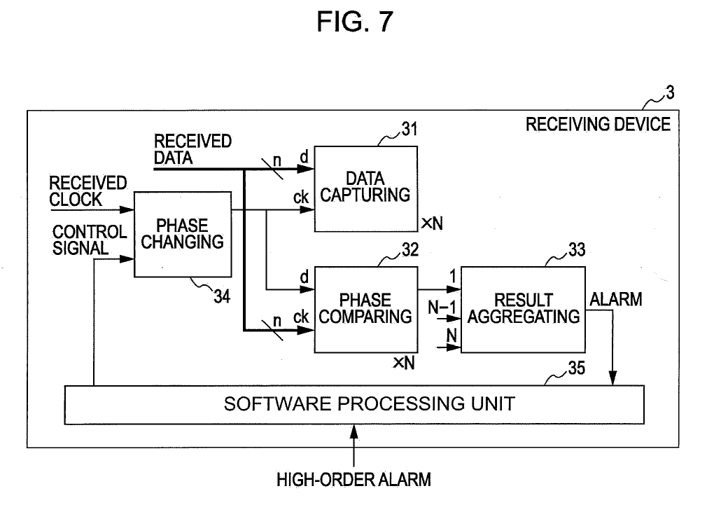

FIG. 7 is a schematic configuration diagram illustrating a schematic configuration of a case in which a receiving device controls the phase of the clock signal to attempt to resolve an abnormality. A receiving device 3 illustrated in the figure has a software processing unit 35 and a clock-phase changing circuit 34, in addition to data capturing circuits 31, phase comparing circuits 32, and a result aggregating circuit 33. The software processing unit 35 receives an alarm issued on high-level layer application software and the clock-phase changing circuit 34 changes the phase of the clock signal received under the control of the software processing unit 35.

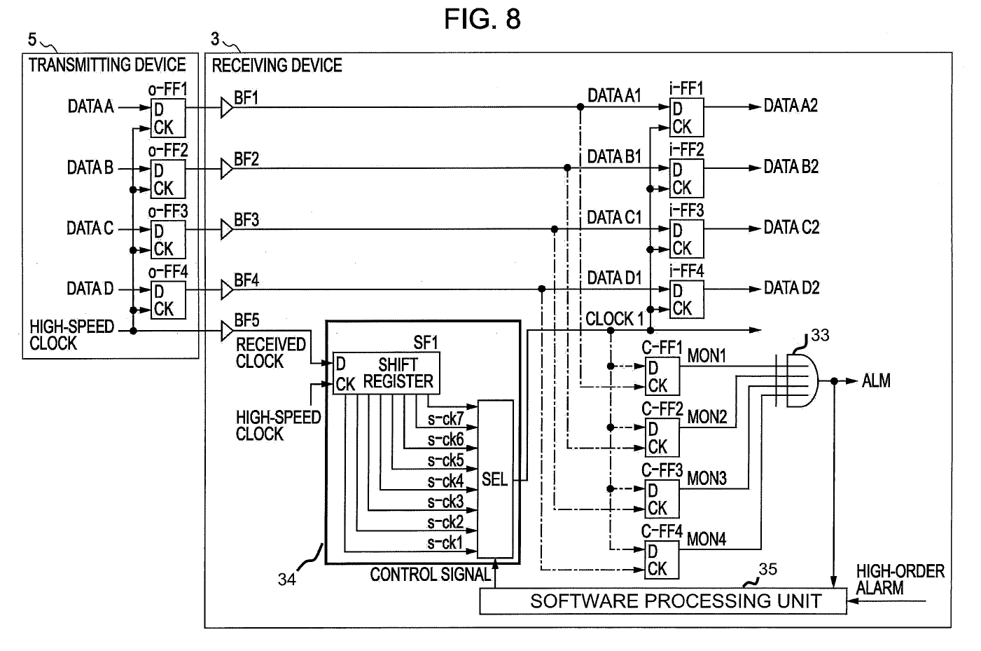

The clock-phase changing circuit 34 is configured, specifically, as illustrated in the circuit diagram in FIG. 8. In the circuit configuration illustrated in the figure, the receiving side in the circuit configuration in a first embodiment has a shift register SF1 for shifting a reception signal by using a high-speed clock and a selector SEL for selecting signals input from the shift register SF1 in accordance with a control signal and for outputting the selected signals. The control signal is input from the software processing unit 35 for achieving a selection control based on the alarm on high-level layer application software and the ALM-output information from the result aggregating circuit.

On the basis of the control signal, the selector SEL selects different-phase clocks output from the shift register SF1 to generate clock signals whose phases are shifted relative to the received clock signal, and supplies the generated clock signals to the phase comparing circuits 32.

The clock signals having the shifted phases are input to the phase comparing circuits 32, (flip flops C-FF1˜4). The phase comparing circuits 32 determine the amount of clock phase shift that provides an alarm ALM absent state. The alarm ALM absent state is a state in which the values of the MON1˜MON4 matching each other. In the alarm ALM absent time, the software processing unit 35 performs selection control to fix the clock selection and completes the selection of the clock phase. The use of the phase-fixed clock signal as a clock for the data capturing circuits allows data processing to be performed in the phase normal state.

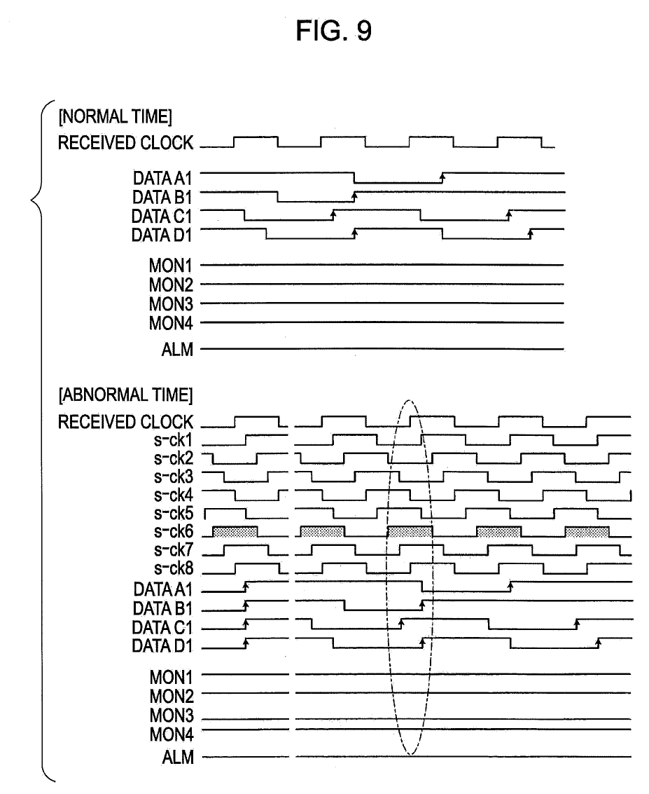

In an abnormal time in a time chart illustrated in FIG. 9, data C1 is in an abnormal state relative to the original reception clock. This is to say, the clock state is in L at the time of the rising edge of the data C1. The software processing unit 35 detects the occurrence of an abnormality, on the basis of an output of the result aggregating circuit 33 or an alarm on high-level application software, and controls the phase changing circuit 34 to shift the phase of the reception clock to generate clock signals s-ck1˜8. When the clock s-ck6 of the clock signals is used, all the rising edges of data A1, B1, C1, and D1 appear when the clock signal is in the H state. Thus, the use of the clock s-ck6 subsequently can resolve an alarm output from the result aggregating circuit 33 as a phase abnormality.

That is, when the receiving device 3 detects a phase abnormality, the clock-phase changing circuit 34 generates clock phases at several timings. The receiving device 3 then selects different-phase clock signals through selection of the control signal and inputs the selected clock signals to the phase comparing circuits 32. When all outputs of the result aggregating circuit 33 become “H”, the clock selection control for the clock-phase changing circuit 34 is stopped and the clock phase is fixed. The use of the phase-fixed clock as a clock for the data capturing circuits allows data processing to be performed in the phase normal state.

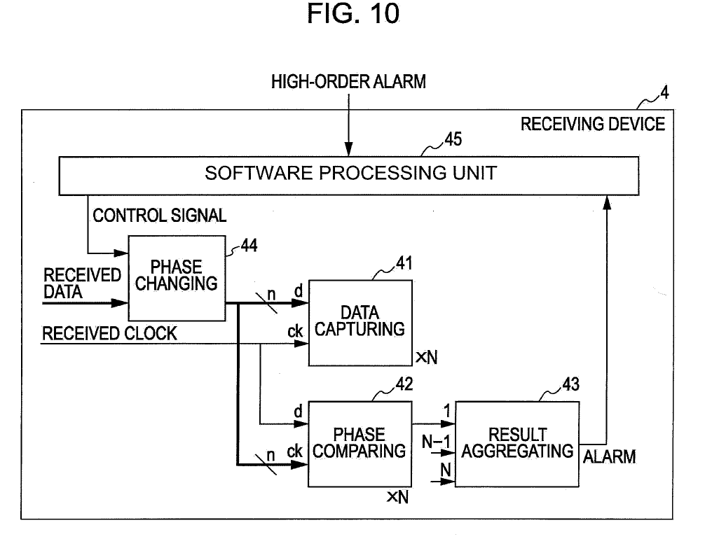

FIG. 10 is a schematic configuration diagram illustrating a schematic configuration of a case in which a receiving device controls the phases of the data signals to attempt to resolve an abnormality. In addition to data capturing circuits 41, phase comparing circuits 42, and a result aggregating circuit 43, a receiving device 4 illustrated in the figure has a data-phase changing circuit 44 and a software processing unit 45 to resolve a phase abnormality.

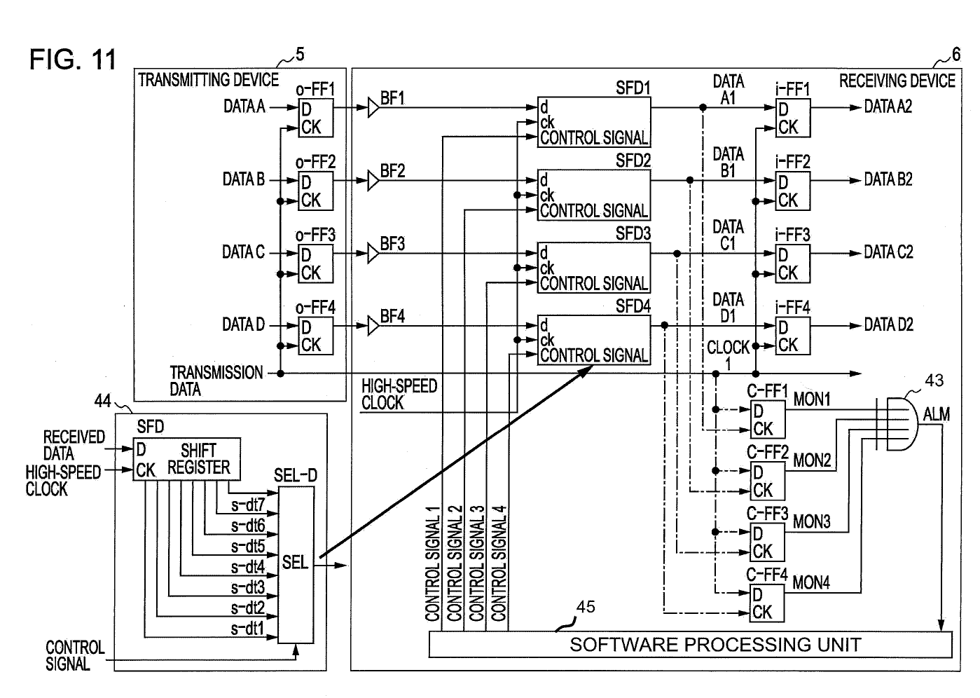

The data-phase changing circuit 44 is configured, specifically, as illustrated in a circuit diagram in FIG. 11. As illustrated in the figure, the data-phase changing circuit 44 has a shift register SFD for shifting received data by using a high-speed clock and a selector SEL-D for selecting signals input from the shift register SFD in accordance with a control signal and for outputting the selected signals. The control signal is input from the software processing unit 45 for achieving selection control based on the alarm on high-level layer application software and the ALM-output information from the result aggregating circuit.

The selector SEL-D selects different-phase data output from the shift register SFD, on the basis of the control signal, and outputs the data. The output data signals are input to the phase comparing circuits C-FF1˜4 for phase comparison. The phase comparing circuits C-FF1˜4 for phase comparison find the amount of data phase shift that provides an alarm ALM absent state. The alarm ALM absent state is a state in values of the MON1˜MON4 matching each other. In the alarm ALM absent time, the software processing unit performs selection control to fix the data-phase selection and completes the selection of the data phase. The use of the phase-fixed data signal as a clock for the data capturing circuits allows data processing to be performed in the phase normal state.

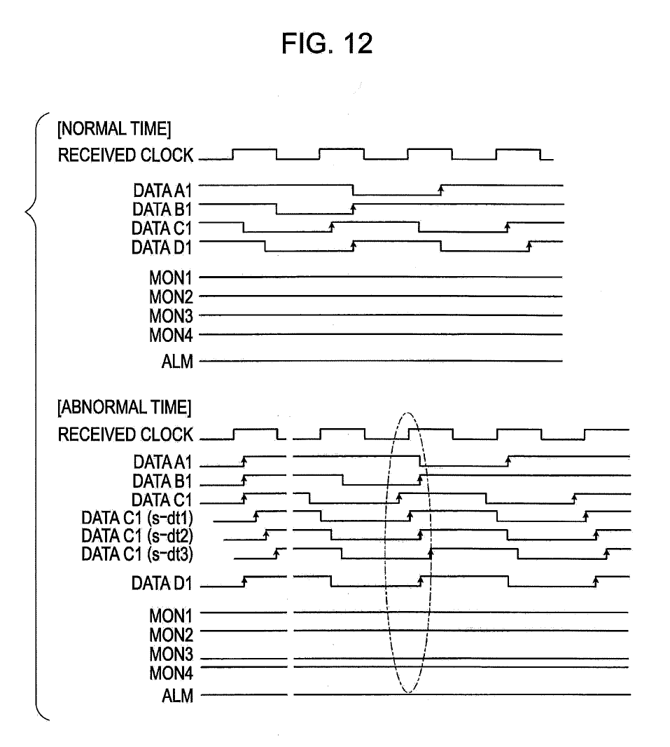

In an abnormal time illustrated in FIG. 12, data C1 of original reception data A1, B1, C1, and D1 is in an abnormal state. The abnormal state is a state in which the clock is L on the rising edge of the data C1. The software processing unit 35 detects the occurrence of an abnormality on the basis of an output of the result aggregating circuit 33 or the alarm on the high-level layer application software, and controls the phase changing circuit 44 to shift the phase of the reception data C1 to create data signals C1 (s-dt˜3). The rising edges of the data signal C1 (s-dt2) and the data signal C1 (s-dt3) of the created data signals appear when the clock signal is in the H state. Thus, subsequently, with respect to the reception data C1, the use of the data signal C1 (s-dt2) or the data signal C1 (s-dt3) can resolve the alarm output from the result aggregating circuit 33 as a phase abnormality.

That is, when the receiving device 4 detects a phase abnormality, the data-phase changing circuit 44 generates data phases at several timings. Then, the receiving device 4 then selects different-phase data signals through selection of the control signal and inputs the selected signals to the phase comparing circuits 42. When all outputs of the result aggregating circuits 43 become “H”, the clock selection control for the data-phase changing circuit 44 is stopped and the data phase is fixed. The use of the phase-fixed data signal as a data signal for the data capturing circuits allows data processing to be performed in the phase normal state.

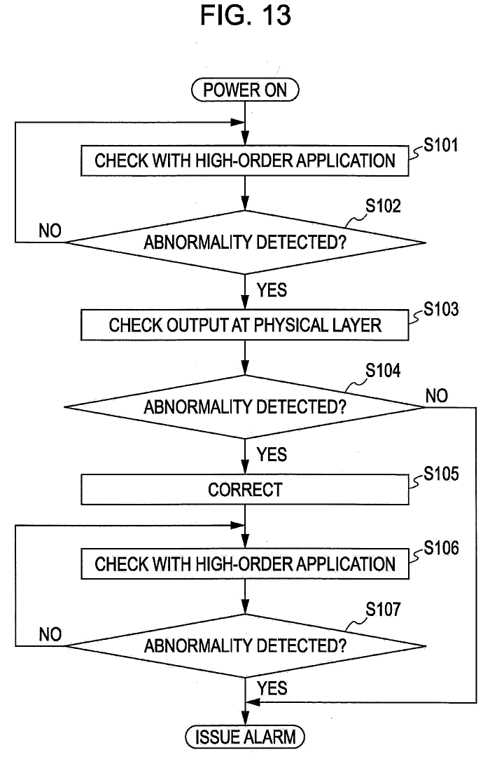

A processing operation of phase-abnormality monitoring processing performed by the receiving device will be described next. FIG. 13 is a flowchart illustrating a processing operation of the phase abnormality monitoring processing. As illustrated in the figure, the receiving device first checks whether or not a high-level application software outputs an error alarm (step S101). As a result, when the high-level layer application software detects an abnormality and performs output (step S102; Yes), and then checks an output of the result aggregating circuit (step S103), which is at the physical layer.

As a result, when an abnormality is also detected at the physical layer (step S104; Yes), correction is performed through phase control of the clock signal and the data signals (step S105), and checking is performed with the high-level layer application software to see whether or not the error has been resolved (step S106).

As a result, when the error cannot be resolved by the correction (step S107; Yes), alarm output is executed. Also, when the error can be resolved, the process returns to the checking with the high-level layer application software (step S101).

As described above, with respect to each of the multiple received data signals, the parallel-data receiving device according to the present embodiment determines whether or not the rising of the data signals is performed when the clock signal is in the H state. When a data signal that rises when the clock signal is in the L state exists, it is determined that an abnormality is occurring in the phase between the data signal and the clock signal. Thus, the phase relationship between the clock and the data is monitored with the simple circuit configuration at low power consumption.

In addition, when a phase abnormality is detected, the phases of the data signals and the clock signals are shifted to thereby automatically attempt to resolve the error.

The configurations and the operations illustrated in the present embodiment are merely examples, and the present invention can be practiced through modification, as needed. For example, although the description in the present embodiment has been given in conjunction with an example of a case in which the rising edges of the data signals occur when the clock signal is in the H state, arbitrary change points, such as the falling edges of the data signals, can be used for the determination, and the present invention is applicable to even a configuration designed so that the change points of the data signal are generated when the clock signal is in the L state.

The following appendices are further disclosed with respect to illustrative embodiments including the above-described embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could, be made hereto without departing from the spirit and scope of the invention.

What is claimed is:

1. A receiving device for receiving a parallel-data including a clock and a plurality of data signals, the receiving device comprising:
a plurality of data capturing circuits for receiving the data signal and the clock, respectively, the data capturing circuit capturing the data signal of the parallel-data on the bases of the clock;
a plurality of phase comparing circuits for receiving the data signal and the clock, respectively, the phase comparing circuit capturing the clock of the parallel-data on the bases of the each data in order to compare a phase between the clock and the data signal; and
an aggregating circuit for monitoring a relationship between the clock and the data signals on the bases of comparison results from the plurality of phase comparing circuits.

2. The receiving device of claim 1, wherein the aggregating circuit determines a phase abnormality status when the at least one data signal is high status and the clock is low status.

3. The receiving device of claim 2, wherein the aggregating circuit determines a phase abnormality status when the at least one data signal is high status and the clock is low status.

4. The receiving device of claim 1, further comprising a clock-phase changing circuit for controlling a phase of the clock signal when the aggregating circuit detects an anomaly of the phase status of the clock signal.

5. The receiving device of claim 4, further comprising a processer for receiving an alarm and for controlling the clock-phase changing circuit when the processer receives the alarm.

6. The receiving device of claim 1, further comprising a plurality of data-phase changing circuits for controlling a phase of the data signal before the data signal inputted into each of the data capturing circuits, when the aggregating circuit detects an anomaly of the phase status of the clock signal.

7. The receiving device of claim 6, further comprising further comprising a processer for receiving an alarm and for controlling the plurality of data-phase changing circuits when the processer receives the alarm.

8. A method for controlling a receiving device for receiving a parallel-data including a clock and a plurality of data signals, the method comprising:
capturing each of the data signal of the parallel-data on the bases of the clock;
capturing the clock for each of the parallel-data on the bases of the each data in order to compare a phase between the clock and the data signal; and
monitoring a relationship between the clock and the data signals on the bases of comparison results from the plurality of phase comparing circuits.

9. The method of the claim 8, wherein the monitoring detects a phase abnormality status when the at least one data signal is high status and the clock is low status.

10. The method of the claim 8, further comprising controlling a phase of the clock signal when the aggregating circuit detects an anomaly of the phase status of the clock signal.

11. The method of the claim 8, further comprising controlling a phase of the data signal before the data signal inputted into each of the data capturing circuits, when the aggregating circuit detects an anomaly of the phase status of the clock signal.

12. A communication system comprising:
a transmitting device for transmit a parallel-data including a clock and a plurality of data signals, the transmitting circuit controlling a duty ratio of the clock; and
a receiving device for receiving the parallel-data, comprising:
a plurality of data capturing circuits for receiving the data signal and the clock, respectively, the data capturing circuit capturing the data signal of the parallel-data on the bases of the clock;
a plurality of phase comparing circuits for receiving the data signal and the clock, respectively, the phase comparing circuit capturing the clock of the parallel-data on the bases of the each data in order to compare a phase between the clock and the data signal; and
an aggregating circuit for monitoring a relationship between the clock and the data signals on the bases of comparison results from the plurality of phase comparing circuits and for determining a phase abnormality status when the at least one data signal is high status and the clock is low status.
